(19) United States
(12) Patent Application Publication
(10) Pub. No.: US 2024/0369748 A1
(43) Pub. Date: Nov. 7, 2024

(54) GRATING COUPLER

(71) Applicant: Kyoto University, Kyoto-shi, Kyoto (JP)

(72) Inventors: Susumu NODA, Kyoto-shi (JP); Takuya INOUE, Osaka-shi (JP); Masahiro YOSHIDA, Kyoto-shi (JP)

(73) Assignee: Kyoto University, Kyoto-shi, Kyoto (JP)

(21) Appl. No.: 18/685,340

(22) PCT Filed: Jul. 12, 2022
(86) PCT No.: PCT/JP2022/027386

§ 371 Date: Feb. 21, 2024

(30) Foreign Application Priority Data
Aug. 24, 2021 (JP) 2021-136313

(51) Int. Cl. G02B 5/18; H01S 5/0225

(52) U.S. Cl. CPC G02B 5/1866; H01S 5/0225

(57) ABSTRACT

A grating coupler includes a grating including a plate-shaped base member and modified refractive index regions having a refractive index different from that of the base member and either being point-like and periodically disposed two-dimensionally or one-dimensionally in the base member, or being linear and periodically disposed one-dimensionally in the base member, where the modified refractive index regions each have a planar shape in which a ratio |κ2|/|κ1| of an absolute value |κ2| of a second coupling coefficient to an absolute value |κ1| of a first coupling coefficient is 3 or more, the first coupling coefficient being an index indicating intensity at which light traveling in a first direction parallel to the base member is reflected in a second direction different by 180° from the first direction, the second coefficient being an index indicating intensity at which light traveling in the second direction is reflected in the first direction.

### TECHNICAL FIELD

The present invention relates to a grating coupler which optically couples optical elements such as an optical integrated circuit and an optical fiber using a grating.

### BACKGROUND ART

Conventionally, in order to couple optical elements such as an optical integrated circuit and an optical fiber, a grating coupler including a grating formed by periodically placing grooves, holes, and the like in a plate-shaped base member is used. In such a grating coupler, light having a specific wavelength corresponding to a period of grooves, holes, or the like among light input (incident) from an end face of a base member (hereinafter, simply referred to as “end face”) is diffracted and output (emitted) from a surface of the base member (hereinafter, simply referred to as “surface”). In reverse, light having a specific wavelength among the light input from the surface can also be output from the end face. By disposing optical elements toward the surface and the end face of a grating coupler respectively, light of a specific wavelength can be transmitted and received between the optical elements. In such a grating coupler, light can be transmitted and received on a region having a larger area on the surface than on the end face. Therefore, by disposing an optical element having a relatively large area of a light transmission/reception portion, such as, for example, an end face of an optical fiber, on the surface, light transmission/reception can be performed with high efficiency.

Non Patent Literature 1 describes a grating coupler in which holes are disposed in a square lattice pattern in a plate-shaped base member made of Si provided on a substrate made of SiO₂. In this literature, two types of grating couplers are manufactured. One is “trapezoidal hole type” in which holes having a trapezoidal planar shape are disposed such that the upper base and the lower base of the trapezoid are parallel to one of (mutually-orthogonal) two directions of a square lattice. The other is “isosceles triangle hole type” in which holes having an isosceles triangle planar shape are disposed such that the base of the isosceles triangle is parallel to one of the two directions. According to this literature, the trapezoidal hole type is considered to have higher efficiency of coupling with an external optical element than the isosceles triangle hole type. In the isosceles triangle hole type, the diffraction of light occurs mainly at the base of the isosceles triangle of each hole, whereas the electric field of light tends to concentrate near the apex of each hole, so that the efficiency of diffraction decreases, thereby also decreasing the efficiency of coupling with external optical elements. On the other hand, in the case of the trapezoidal hole type, the concentration of the electric field is less likely to occur than in the case of the isosceles triangle hole type, and the electric field intensity can be made relatively high in the vicinity of the base where light diffraction mainly occurs. Therefore, the efficiency of diffraction and the efficiency of coupling with external optical elements can be made higher than in the case of the isosceles triangle hole type.

### CITATION LIST

### Non Patent Literature

Non Patent Literature 1: Akio Mizutani and one other, “A grating coupler with a trapezoidal hole array for perfectly vertical light coupling between optical fibers and waveguides” Applied Physics Express, The Japan Society of Applied Physics, Nov. 21, 2017, Vol. 10, p. 122501.

Non Patent Literature 2: Yong Liang and four others, “Three-dimensional coupled-wave model for square-lattice photonic crystal lasers with transverse electric polarization: A general approach”, Physical Review B, (USA), American Physical Society, Nov. 22, 2011, Vol. 84, p. 195119.

### SUMMARY OF INVENTION

### Technical Problem

In the grating coupler described in Non Patent Literature 1, in a case where light is input from the end face, a part of the light input from the end face is reflected by the grooves or the holes in both the trapezoidal hole type and the isosceles triangle hole type, so that reflected light having a traveling direction changed by 180° is generated, and the reflected light is emitted from the end face. Thus, when the reflected light is emitted from the end face, the efficiency of outputting the light from the surface is reduced. In addition, there is a risk that the emitted light enters (reversely enters) the optical element on the input side, thereby causing a failure of the optical element on the input side.

In addition, in a case where light is input from the surface, the light mainly travels in the base member from the longer one of the lower base and the upper base of the trapezoid of holes to the shorter one (in the case of the trapezoid hole type), or from the base of the isosceles triangle to the apex (in the case of the isosceles triangle hole type), but may also travel in the direction different from that by 180°. In this way, light traveling in directions different by 180° becomes a loss.

An object of the present invention is to provide a grating coupler capable of efficiently outputting input light.

### Solution to Problem

A grating coupler made to solve the above problem includes
a grating including a plate-shaped base member and modified refractive index regions having a refractive index different from that of the base member, the modified refractive index regions either being point-like and periodically disposed two-dimensionally or one-dimensionally in the base member, or being linear and periodically disposed one-dimensionally in the base member,
in which the modified refractive index regions individually have a planar shape in which a ratio |κ2|/|κ1| of an absolute value |κ2| of a second coupling coefficient to an absolute value |κ1| of a first coupling coefficient is 3 or more, the first coupling coefficient being an index indicating intensity at which light traveling in a first direction parallel to the base member is reflected in a second direction different by 180° from the first direction, the second coefficient being an index indicating intensity at which light traveling in the second direction is reflected in the first direction.

The modified refractive index region refers to a region having a refractive index different from that of the base member as described above, and is typically formed of air (an empty hole in the case of point shape, an empty groove in the case of linear). As another example, the modified refractive index region may be formed by embedding an object made of a material different from that of the base member in the base member. When the modified refractive index regions are point-like, they are periodically disposed two-dimensionally (square lattice shape, rectangular lattice shape, etc.) or one-dimensionally, and when the modified refractive index regions are linear, they are periodically disposed one-dimensionally. The modified refractive index region may be provided over the entire thickness of the base member (so as to penetrate the base member), or may be provided only in a part of the thickness of the base member. In the latter case, the modified refractive index region may be provided from one surface of the base member (so as to appear on the one surface and not appear on the other surface), or may be provided only inside the base member (so as not to appear on either of both surfaces of the base member).

The coupling coefficient is an index indicating intensity of light in which light traveling in the grating is diffracted in a 180° direction (that is, reflected). The 180° reflected light is formed by a sum of light generated when the traveling direction of light is directly changed by 180° by the grating and light generated when the traveling direction is changed by 180° while interacting with light output perpendicularly to the base member (in a direction different from the traveling direction by 90°). The first coupling coefficient κ1 is an index indicating the intensity of light in which light traveling in the predetermined first direction in the grating is reflected by 180° (in the second direction), and the second coupling coefficient κ2 is an index indicating the intensity of light in which light traveling in the second direction in the grating is reflected by 180° (in the first direction). The first coupling coefficient κ1 and the second coupling coefficient κ2 can be obtained on the basis of the method described in Non Patent Literature 2 on the basis of the structure of the modified refractive index region (shape, size, and refractive index).

According to the grating coupler of the present invention, by providing the modified refractive index region having the planar shape in which |κ2|/|κ1| is 3 or more, the ratio of the intensity of the light reflected toward the second direction among the light traveling in the first direction in the grating can be suppressed to approximately 10% or less. Therefore, when light is input from the end face in the grating coupler according to the present invention, the efficiency of outputting light from the surface can be increased by inputting light so as to travel in the first direction. In addition, since the intensity of light entering (reversely entering) the optical element disposed on the input end face can be suppressed, it is possible to reduce the possibility of failure of the optical element.

When the planar shape of the modified refractive index region does not have 180° rotational symmetry, the absolute value |κ1| of the first coupling coefficient and the absolute value |κ2| of the second coupling coefficient have different values. In the present invention, since |κ2|/|κ1| is 3 or more, the planar shape of the modified refractive index region does not have 180° rotational symmetry.

For the grating coupler described in Non Patent Literature 1 including holes having trapezoidal and isosceles triangular planar shapes, |κ2|/|κ1| was calculated by the method described in Non Patent Literature 2 on the basis of parameters such as lengths of sides of the planar shape described in Non Patent Literature 1. As a result, the value of |κ2|/|κ1| is 1.09 when the planar shape is trapezoidal, and 1.64 when the planar shape is isosceles triangular, and these values are not included in the range of “3 or more” defined in the present invention.

In the present invention, it is preferable that each of the modified refractive index regions includes a pair of a first partial modified refractive index region and a second partial modified refractive index region, the second partial modified refractive index region being different from the first partial modified refractive index region in either shape or area, or in both shape and area.

By using such a modified refractive index region formed by a pair of the first partial modified refractive index region and the second partial modified refractive index region, asymmetry of the planar shape can be easily introduced, and the value of |κ2|/|κ1| can be easily increased.

In the present invention, in addition to the first partial modified refractive index region and the second partial modified refractive index region, each of the modified refractive index regions may further include one or two or more partial modified refractive index regions different from the first partial modified refractive index region or the second partial modified refractive index region in either shape or area, or in both shape and area.

In the present invention, simultaneously with the first direction, light can also be input from a third direction parallel to the base member and perpendicular to the first direction. In this case, it is necessary to input the input light so that the input light from the first direction and the input light from the third direction have the same phase and the same amplitude in the grating. In addition, in this case, the first coupling coefficient κ1 is an index indicating intensity reflected at the same phase and the same amplitude in the second direction and the fourth direction different by 180° from the first direction and the third direction among light traveling at the same phase and the same amplitude in the first direction and the third direction. Similarly, the second coupling coefficient κ2 is an index indicating intensity reflected at the same phase and the same amplitude in the first direction and the third direction among light traveling at the same phase and the same amplitude in the second direction and the fourth direction. With respect to the first coupling coefficient κ1 and the second coupling coefficient κ2, when |κ2|/|κ1| is 3 or more, it is possible to suppress, to approximately 10% or less, the ratio of the intensity of light in which light traveling in the first direction and the third direction in the grating is reflected respectively in directions different by 180° (the second direction and the fourth direction). Therefore, with respect to both the light traveling in the first direction and the light traveling in the third direction, the efficiency of outputting the light from the surface can be increased, and it is possible to suppress the intensity of the reversely entering light.

The grating coupler according to the present invention can further include a light amplification layer configured to amplify light having a predetermined wavelength in the base member in the grating or on a surface of the base member.

Here, the predetermined wavelength is a wavelength corresponding to the period length of the arrangement of the modified refractive index regions. Specifically, the wavelength in the grating (which is shorter than the wavelength in vacuum at the same frequency) may be an integral multiple or an integral fraction of the period length. An active layer used in a laser element or the like can be applied to the light amplification layer.

A grating coupler including such light amplification layer can be used as an optical amplifier that amplifies input light by the light amplification layer and then outputs the amplified input light with high efficiency.

### Advantageous Effects of Invention

According to the grating coupler of the present invention, it is possible to efficiently output input light.

### BRIEF DESCRIPTION OF DRAWINGS

FIG. 1 is a perspective view illustrating a grating coupler according to a first embodiment of the present invention.

FIG. 2 is a top view illustrating the grating coupler of the first embodiment.

FIG. 3 is an A cross-sectional view illustrating the grating coupler of the first embodiment.

FIG. 4 is a diagram illustrating parameters for obtaining a first coupling coefficient and a second coupling coefficient in the grating coupler of the first embodiment.

FIG. 5 is a diagram illustrating a mechanism in which reflected light is generated in the grating.

FIG. 6 is a graph illustrating an example in which a real part R and an imaginary part I of a Hermitian coupling coefficient are calculated in the grating coupler of the first embodiment.

FIG. 7A is a diagram illustrating a result obtained by calculation of distributions of the intensity of output light and the intensity of reflected light when light is input from an input port, and FIG. 7B is a diagram illustrating a result obtained by calculation of distributions of the intensity of output light and the intensity of reflected light when light is input from an opposite end of the input port, in a case of d=0.265a₁ and f₁=3.80% in which |κ2|/|κ1| is 3 or more in the grating coupler of the first embodiment.

FIG. 8 is a top view illustrating a modification of the grating coupler of the first embodiment, in which point-like modified refractive index regions are disposed one-dimensionally.

FIGS. 9A and 9B are graphs illustrating, in a case of d=0.286a and an area S₁ of the first partial modified refractive index region=0.0440a² in which |κ2|/|κ1| is 3 or more in a waveguide grating coupler of the example in FIG. 8, a result obtained by calculating output light, reflected light, and transmitted light when light is input from an input port side (first partial modified refractive index region side) and a result obtained by calculating output light, reflected light, and transmitted light when light is input from an opposite side of the input port (second partial modified refractive index region side).

FIGS. 10A and 10B are graphs illustrating, in a case of d=0.286a and S₁=0.0475a² in which |κ2|/|κ1| is 3 or more in the grating coupler of the example in FIG. 8, a result obtained by calculating output light, reflected light, and transmitted light when light is input from the input port side (first partial modified refractive index region side) and a result obtained by calculating output light, reflected light, and transmitted light when light is input from the opposite side of the input port (second partial modified refractive index region side).

FIG. 11 is a top view illustrating a structure that can be operated as a waveguide grating coupler in a case where d and S₁ have modified refractive index regions of values illustrated in the example of FIGS. 10A and 10B.

FIG. 12 is a top view illustrating a modification of the grating coupler of the first embodiment, in which linear modified refractive index regions are disposed one-dimensionally.

FIGS. 13A and 13B are cross-sectional views of an optical amplifier as another modification of the grating coupler of the first embodiment, illustrating an example in which a light amplification layer is provided on a surface of a base member of the grating and an example in which the light amplification layer is provided in the base member.

FIG. 14 is a top view illustrating a grating coupler according to a second embodiment of the present invention.

FIG. 15 is a diagram illustrating parameters for obtaining a first coupling coefficient and a second coupling coefficient in the grating coupler of the second embodiment.

FIG. 16 is a graph illustrating an example in which a real part R and an imaginary part I of a Hermitian coupling coefficient are calculated in the grating coupler of the second embodiment.

FIG. 17 is a diagram illustrating results of calculation of distributions of intensity of output light and intensity of reflected light when light is input from first and second input ports in a case of d=0.278a and 2x=1.5 nm in which |κ2|/|κ1| is 3 or more in the grating coupler of the second embodiment.

### DESCRIPTION OF EMBODIMENTS

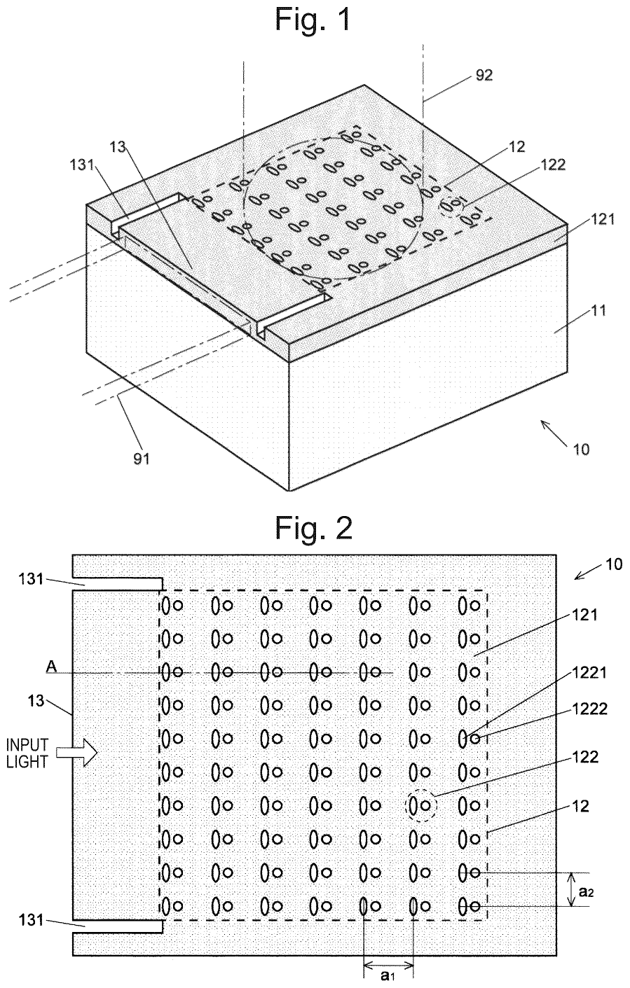

Embodiments of a grating coupler according to the present invention will be described with reference to FIGS. 1 to 17.

### (1) First Embodiment

FIG. 1 is a perspective view illustrating a grating coupler 10 of a first embodiment. The grating coupler 10 includes a pedestal 11 made of silicon dioxide (SiO₂) and having a rectangular planar shape, a rectangular plate-shaped base member 121 made of silicon (Si) and formed on a surface of the pedestal 11, a large number of modified refractive index regions 122 formed by holes provided in the base member 121, and an input port (light input portion) 13 provided in one side (an end portion on a starting point side in a first direction to be described later) of four sides of the rectangle of the base member 121. The base member 121 and the modified refractive index regions 122 together constitute a grating 12. A surface of the base member 121 opposite to the pedestal 11 is a space (air).

In the present embodiment, the entire lower surface of the base member 121 is supported by the pedestal 11, but a part of the lower surface of the base member 121 (for example, only the vicinity of two opposing sides of the rectangle of the base member 121) may be supported by some member. In addition, the materials of the pedestal 11 and the base member 121 are not limited to the above examples, and other materials may be used. The modified refractive index region 122 may be formed by embedding an object made of a material having a refractive index different from that of the base member 121 in the base member instead of the holes. In addition, in FIG. 1 and the like, about several tens of modified refractive index regions 122 are drawn, but actually, more modified refractive index regions 122 are provided in the base member 121.

As illustrated in the top view of FIG. 2, each of the modified refractive index regions 122 is formed by disposing a first partial modified refractive index region 1221 and a second partial modified refractive index region 1222 having a planar shape and an area different from those of the first partial modified refractive index region 1221 to be separated from each other. Regarding the planar shapes, the first partial modified refractive index region 1221 has an elliptical shape, and the second partial modified refractive index region 1222 has a circular shape. Since the planar shapes and the areas of the first partial modified refractive index region 1221 and the second partial modified refractive index region 1222 are different as described above, the planar shape of the entire modified refractive index region 122 does not have 180° rotational symmetry.

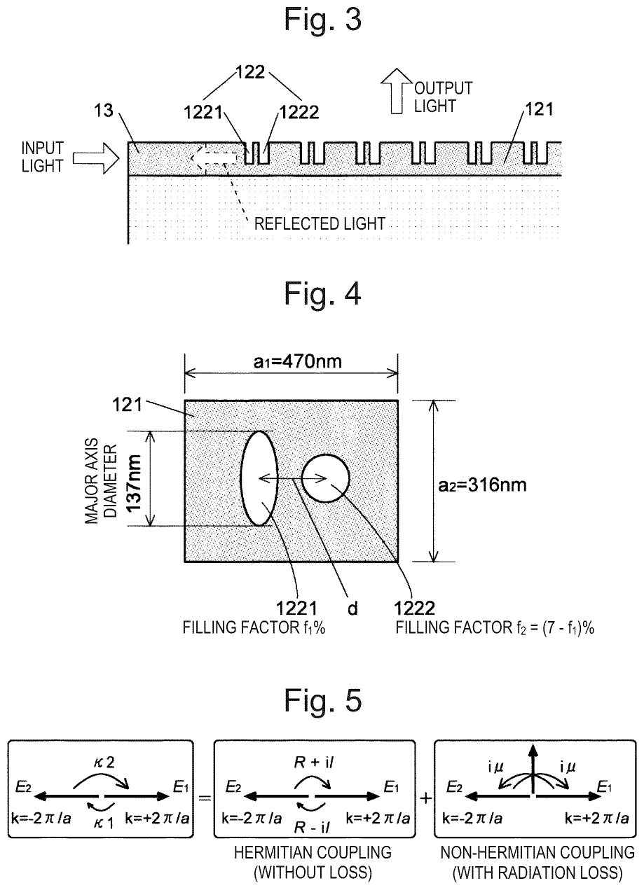

In addition, the shape of each of the modified refractive index regions 122 is designed such that the ratio |κ2|/|κ1| of a first coupling coefficient κ1 and a second coupling coefficient κ2 is 3 or more, and details of the design will be described later. In the first coupling coefficient κ1 in the present embodiment, light traveling from the input port 13 toward the opposite side of one side of the rectangle of the base member 121 provided with the input port 13 (The direction in which this light travels is referred to as “first direction”. This is a direction from left to right in FIGS. 2 and 3.) is an index indicating the intensity reflected by the modified refractive index region 122 toward a direction (referred to as “second direction”) different from the first direction by 180°. The second coupling coefficient κ2 is an index indicating the intensity at which light traveling in the second direction is reflected by the modified refractive index region 122 toward the first direction.

In the example illustrated in FIG. 2, the planar shape of the first partial modified refractive index region 1221 is elliptical, and the planar shape of the second partial modified refractive index region 1222 is circular. The planar shapes of these partial modified refractive index regions may be other shapes. Further, only one of the planar shape and the area of the second partial modified refractive index region 1222 may be made different from that of the first partial modified refractive index region 1221.

The modified refractive index regions 122 are disposed one by one on lattice points of the rectangular lattice within a range of the rectangular base member 121 excluding the vicinity of the four sides of the rectangle. One of the two basic translation vectors of the rectangular lattice is parallel to the first direction and the second direction, and the other is perpendicular to the first direction and the second direction. The lattice constant of the rectangular lattice is set such that a lattice constant a₁ in the direction parallel to the first direction and the second direction is longer than a lattice constant a₂ in the direction perpendicular to the first direction and the second direction. The minor axis of the planar shape of the first partial modified refractive index region 1221 faces a direction parallel to the first direction and the second direction, and the centroid of the first partial modified refractive index region 1221 and the centroid of the second partial modified refractive index region 1222 are separated in a direction parallel to the first direction and the second direction.

As illustrated in the cross-sectional view of FIG. 3, the modified refractive index region 122 is provided from the upper surface side of the base member 121 to a predetermined depth in the thickness direction without penetrating the base member 121. In the present invention, the modified refractive index region 122 may be formed so as to penetrate the base member 121, or the modified refractive index region 122 may be provided only inside the base member 121 by providing a lid made of the same material as that of the base member 121 on the upper surface of the modified refractive index region 122.

The input port 13 is provided in a portion of the rectangular base member 121 on one side of the rectangle where the modified refractive index regions 122 are not disposed (the grating 12 is not formed), and corresponds to a portion between two grooves 131 extending from the grating 12 toward one side of the rectangle.

An input-side optical element 91 is disposed at an end of the base member 121 outside the input port 13, and an output-side optical element 92 is disposed on an upper surface (a surface opposite to the pedestal 11) of the grating 12. An optical IC or the like can be used for the input-side optical element 91, and an optical fiber or the like can be used for the output-side optical element 92.

The operation of the grating coupler 10 of the present embodiment will be described. When the grating coupler 10 is used, the input-side optical element 91 is installed at the end portion of the input port 13 such that the traveling direction of the input light emitted by the input-side optical element 91 is parallel to the base member 121. As the input light, light having a wavelength of the same length as a₁ which is the lattice constant of the grating 12 in the traveling direction of the input light is used. When the wavelength of the input light is determined in advance, the lattice constant at is set in accordance with the wavelength. The wavelength of the input light here is a wavelength in the grating 12, and is shorter than the wavelength in vacuum because the effective refractive index in the grating 12 is larger than 1.

The input light input from the input port 13 travels in the first direction in the grating 12. Then, the input light is diffracted by the modified refractive index regions 122 disposed periodically in the grating 12. At this time, since the wavelength of the input light in the grating 12 coincides with the lattice constant a₁ in the traveling direction of the input light, the diffracted light diffracted in the direction perpendicular to the base member 121 is intensified by interference. As a result, diffracted light diffracted in a direction perpendicular to the base member 121 is extracted from the surface of the base member 121 as output light (FIG. 3). By disposing the output-side optical element 92 on this surface (for example, as illustrated in FIG. 1, with one end of an optical fiber that is the output-side optical element 92 being directed to this surface), the output light is captured by the output-side optical element 92. Thus, the input-side optical element 91 and the output-side optical element 92 are optically coupled by the grating coupler 10.

On the other hand, a part of the input light traveling in the first direction in the grating 12 is reflected by the modified refractive index regions 122 and becomes reflected light traveling in the second direction. In the grating coupler 10 of the present embodiment, since the shape and the size of the modified refractive index region 122 are designed such that the ratio |κ2|/|κ1| of the first coupling coefficient κ1 and the second coupling coefficient κ2 is 3 or more, the intensity of the reflected light is generally suppressed to 10% or less of the intensity of the incident light. Therefore, it is possible to increase the output efficiency by suppressing a decrease in the intensity of the output light, and it is possible to suppress a failure of the input-side optical element 91 due to reverse entry of the reflected light.

Hereinafter, an example in which the shape and size of the modified refractive index region 122 are designed so that |κ2|/|κ1| is 3 or more will be described in detail, and a result of simulating output light and reflected light in a case where the modified refractive index region 122 having the designed shape and size is used will be described. The design described below is an example. Even in a case where the modified refractive index region has another shape, it is possible to appropriately perform the so that |κ2|/|κ1| is 3 or more after the first coupling coefficient κ1 and the second coupling coefficient κ2 are calculated using the method described in Non Patent Literature 2.

Parameters for defining κ1 and κ2 used in this design example will be described with reference to FIG. 4. The refractive index of the base member 121 (Si) was set to 3.4, and the refractive index of the modified refractive index region 122 (air) was set to 1. The lattice constants were a₁=470 nm and a₂=316 nm. The thickness of the base member 121 was 330 nm, and the thickness of the modified refractive index region 122 was 220 nm. The wavelength of the input light and the output light in the grating 12 is 470 nm which is the same value as a₁. Since the effective refractive index of the grating 12 depends on the size of the modified refractive index region 122, the wavelengths of the input light and the output light in vacuum also depend on the size of the modified refractive index region 122.

As a distance d between the centroid of the first partial modified refractive index region 1221 and the centroid of the second partial modified refractive index region 1222, three examples of 0.260a₁, 0.265a₁, and 0.270a₁ were prepared.

The planar shape of the first partial modified refractive index region 1221 and the planar shape of the second partial modified refractive index region 1222 were determined such that the sum f=f₁+f₂ of a filling factor f₁ of the first partial modified refractive index region 1221 and a filling factor f₂ of the second partial modified refractive index region 1222 was 0.07 (7%). Here, the filling factor f₁ (f₂) of the first (second) partial modified refractive index region 1221 (1222) is defined by a value obtained by dividing the area of the planar shape of the first (second) partial modified refractive index region 1221 (1222) by the area (=a₁×a₂) of the unit lattice. The length of the major axis of the ellipse of the first partial modified refractive index region 1221 is fixed to 137 nm, and then, for five examples in which the filling index f₁ of the first partial modified refractive index region 1221 is 3.75%, 3.80%, 3.85%, 3.90%, and 3.95%, the length of the minor axis of the ellipse and the diameter of the circle of the second partial modified refractive index region 1222 were determined such that the filling index f of the modified refractive index region 122 is 7%.

For 15 examples obtained by combining the examples of three intercentroid distances d and the examples of the filling factor f₁ of the five first partial modified refractive index regions 1221 described above, a Hermitian coupling coefficient R±iI and a non-Hermitian coupling coefficient iμ (i is an imaginary unit) for obtaining the first coupling coefficient κ1 and the second coupling coefficient κ2 were obtained using the method described in Non Patent Literature 2.

Here, the Hermitian coupling coefficient R±iI is a coefficient indicating an index in which the traveling direction of light changes by 180° without loss as illustrated in a frame described as “HERMITIAN COUPLING” in FIG. 5. In the Hermitian coupling coefficient, a value at change from the second direction to the first direction (referred to as R+iI) and a value at change from the first direction to the second direction (referred to as R−iI) are in a complex conjugate relationship. The non-Hermitian coupling coefficient iμ is, as shown in a frame described as “NON-HERMITIAN COUPLING” in FIG. 5, a coefficient indicating an index in which the traveling direction of light changes, while accompanying a radiation loss in a direction different from the initial direction by 90° (direction perpendicular to the base member 121), in a direction different from the initial direction by 180°. Regarding the non-Hermitian coupling coefficient, the value at change from the second direction to the first direction and the value at change from the first direction to the second direction are the same value iμ. The sum of light whose traveling direction changes by 180° without these losses and light whose traveling direction changes by 180° with a radiation loss is reflected light. The first coupling coefficient κ1 and the second coupling coefficient κ2 are represented by using the Hermitian coupling coefficient and the non-Hermitian coupling coefficient, respectively, as follows.

$$κ1 = R - iI + i μ$$

$$κ2 = R + i I + i μ$$

The relationship between the first coupling coefficient κ1 and the second coupling coefficient κ2, and reflectance R1 at which light propagating in the first direction is reflected in the second direction and reflectance R2 at which light propagating in the second direction is reflected in the first direction is as follows.

$$R 1 / R 2 = {\vert κ1 / κ2 \vert}^{2}$$

When |κ2|/|κ1| is 3 or more, R1/R2 is 1/9 or less, and the reflectance to the input wave can be suppressed to approximately 10% or less (strictly, 11.1 . . . % or less).

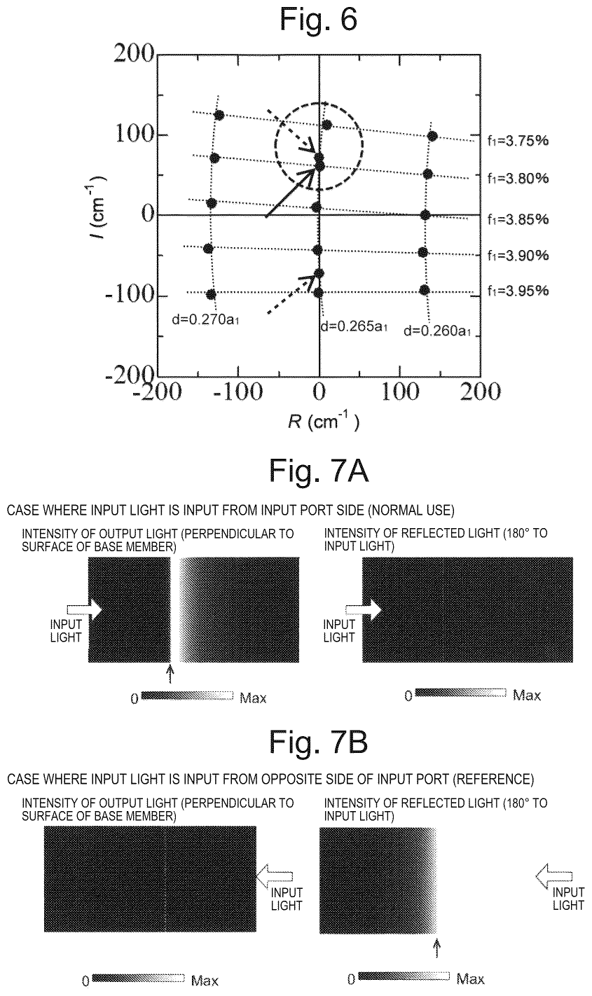

The results of calculating the values of R and I in the Hermitian coupling coefficient R±iI are shown in FIG. 6. The calculation results of the value μ representing the imaginary part (the real part is 0) of the non-Hermitian coupling coefficient hardly depend on the intercentroid distance d and the filling factor f1 of the first partial modified refractive index region, and were almost the same value (about 70 cm⁻¹). Among the 17 data points illustrated in FIG. 6, 15 data points excluding 2 data points indicated by dashed line arrows indicate the values of R and I according to each of the 15 examples in which the intercentroid distances d and the filling factors f₁ of the first partial modified refractive index region 1221 are combined. The values of the intercentroid distance d at each data point and the filling factor f₁ of the first partial modified refractive index region 1221 correspond to numerical values described on a curve of a thin dashed line intersecting in the vicinity of each data point. The two pieces of data indicated by the dashed arrows are points at which R=0, I=+μ, and R=0, I=−μ, respectively. The former indicates R and I when the intensity of the reflected light becomes 0, and the latter indicates R and I when the intensity of the reflected light becomes 1. At data points within a circle indicated by a thick dashed line in FIG. 6 (d=0.265a₁, f₁=3.75%, and d=0.265a₁, f₁=3.80%), |κ2|/|κ1| is 3 or more.

FIGS. 7A and 7B illustrate results obtained by calculating intensity distributions of output light output in a direction perpendicular to the base member 121 and reflected light reflected in the grating 12 and having a traveling direction changed by 180° in a case of d=0.265a₁ and f₁=3.80% in which |κ2|/|κ1| is 3 or more. Here, the calculation was performed for two cases of a normal case (FIG. 7A) where the input light was input from the input port 13 (the input light travels in the first direction) and a case as a reference (FIG. 7B) where the input light was input from the end portion of the base member 121 on the opposite side of the input port 13 (the input light travels in the second direction).

As a result, it can be seen that, when light is input from the input port 13, output light is output in a direction perpendicular to the base member 121 from an end portion of the grating 12 on the input port 13 side (a portion indicated by a vertical arrow in the left diagram of FIG. 7A) to the inside of the grating 12, whereas reflected light is hardly generated (right diagram of FIG. 7A, in which a dashed line portion is an end portion of the grating 12 on the input port 13 side). From this result, it can be seen that the grating coupler 10 of the first embodiment can efficiently output the light input from the input port 13 in the direction perpendicular to the base member 121 in the case of d=0.265a₁ and f₁=3.80%.

On the other hand, in a case where light is input from the opposite side of the input port 13, it can be seen that most of the input light is reflected at an end portion of the grating 12 on the opposite side of the input port 13 (a portion indicated by a vertical arrow in the right diagram of FIG. 7B) and a region slightly entering the grating 12 from the end portion, and little light is output in a direction perpendicular to the base member 121.

Heretofore, the case of using the modified refractive index region 122 including a pair of the first partial modified refractive index region 1221 and the second partial modified refractive index region 1222 has been described as an example. As long as the planar shape satisfies the condition that |κ2|/|κ1| is 3 or more, a modified refractive index region including only one region having a refractive index different from that of the base member 121 may be used, or a modified refractive index region including three or more partial modified refractive index regions may be used.

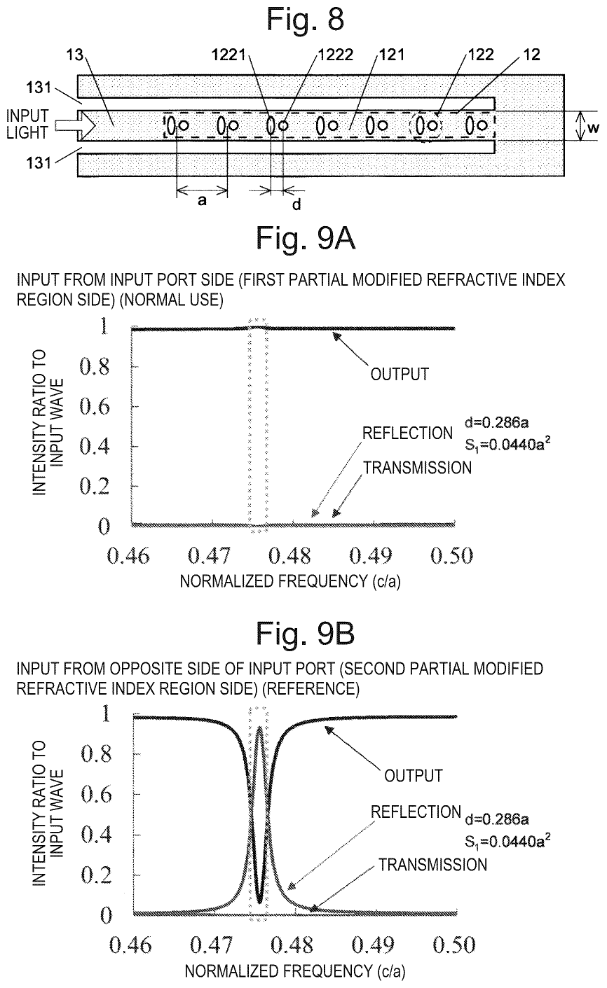

In addition, although the example in which the point-like modified refractive index regions 122 are two-dimensionally disposed has been described so far, the point-like modified refractive index regions 122 may be one-dimensionally disposed as illustrated in FIG. 8. In this example, in order to prevent light from leaking in a direction perpendicular to a direction in which the modified refractive index regions 122 are disposed in a plane of the base member 121 (side of the grating 13), two grooves 131 extending from the input port 13 are provided to extend not only to a portion where the modified refractive index regions 122 are not disposed (or where the grating 12 is not formed) but also to the sides (upper and lower portions of the grating 12 in FIG. 8) of the partial grating 12.

Similarly to the example illustrated in FIG. 1 and the like, the modified refractive index region 122 has a shape in which the elliptical first partial modified refractive index region 1221 and the circular second partial modified refractive index region 1222 are combined, and in each modified refractive index region 122, the first partial modified refractive index region 1221 is disposed closer to the input port 13 than the second partial modified refractive index region 1222, and the minor axis of the elliptical shape of the first partial modified refractive index region 1221 is directed in a direction parallel to the groove 131.

In the example illustrated in FIG. 8, while light passes through a one-dimensional portion between the two grooves 131, in other words, a waveguide portion, light is output in a direction perpendicular to the base member 121. Hereinafter, the grating coupler having such a waveguide structure is referred to as “waveguide grating coupler”.

The following calculation was performed for the waveguide grating coupler illustrated in FIG. 8. In this calculation, the period length (arrangement interval) a of the modified refractive index regions 122 was 0.720 μm, the material of the base member 121 was Si (refractive index 3.4), the width w of the base member 121 between the two grooves was 0.480 μm, and the thickness of the base member 121 was 0.22 μm. In addition, the sum S=S₁+S₂ of the area S₁ of the first partial modified refractive index region 1221 and the area S₂ of the second partial modified refractive index region 1222 was 0.08a². As a result, the filling factor of the modified refractive index region 122 becomes f=S/(a×w) =0.08a/w=0.12. The ellipticity of the first partial modified refractive index region 1221 was set to 10S₁/a². Calculation was performed in an example in which 150 such modified refractive index regions 122 were disposed one-dimensionally.

First, in a case where the distance (intercentroid distance) d between the centroid of the first partial modified refractive index region 1221 and the centroid of the second partial modified refractive index region 1222 is set to 0.286a, and the area S₁ of the first partial modified refractive index region 1221 is set to 0.0440a² (waveguide grating coupler of the first example), the real part R and the imaginary part I of the Hermitian coupling coefficient and the imaginary part μ (the real part is 0) of the non-Hermitian coupling coefficient were obtained. The result was I≈μ≈350 cm⁻¹, and the absolute value of R was a value sufficiently smaller than I and μ (|R|<50 cm⁻¹). From these R, I, and μ, the absolute value |κ1| of the first coupling coefficient κ1=R−iI+iμ is sufficiently smaller than the absolute value |κ2| of the second coupling coefficient κ2=R+iI+iμ. Therefore, the waveguide grating coupler of the first example satisfies the requirement that |κ2|/|κ1| is 3 or more.

For the waveguide grating coupler of the first example, the intensity of the emitted light in which the light (input light) input from the input port 13 is emitted in the direction perpendicular to the base member 121, the reflected light reflected by the modified refractive index region 122 and returned to the input port 13 side, and the transmitted light transmitted through the grating and flowing out to the waveguide end portion on the opposite side of the input port 13 were obtained by calculation. The results are shown in FIG. 9A. As illustrated in the figure, it can be seen that most of the input light is output without being reflected or transmitted over the entire range (0.45 to 0.50) of the calculated normalized frequency by the normal use of inputting light from the input port 13, and functions as a grating coupler. Here, a value obtained by multiplying the normalized frequency by c/a (c is the speed of light) represents the frequency of light in the waveguide grating coupler having a period length of a.

In addition, for reference, FIG. 9B illustrates a result obtained by calculating intensity of emitted light, reflected light (light returning to the waveguide end portion), and transmitted light (light flowing out to the input port 13) when light is input from the waveguide end portion on the opposite side of the input port 13. In this case, it can be seen that strong reflected light is generated at a normalized frequency of around 0.475 (a region surrounded by a dashed line in FIGS. 9A and 9B), and the grating coupler does not sufficiently function as a grating coupler. In this case, the configuration illustrated in FIG. 9A can be used as a reflector.

Next, as the waveguide grating coupler of the comparative example, in a case where the area S₁ of the first partial modified refractive index region 1221 is set to 0.0475a² and the other parameters are set to the same values as those of the first example, the real part R and the imaginary part I of the Hermitian coupling coefficient and the imaginary part μ of the non-Hermitian coupling coefficient were obtained. The result was I≈−350 cm⁻¹, μ≈−350 cm⁻¹, and |R|<50 cm⁻¹. From these R, I, and μ, the absolute value |κ1| of the first coupling coefficient κ1=R−iI+iμ is sufficiently larger than the absolute value |κ2| of the second coupling coefficient κ2=R+iI+iμ. Therefore, the waveguide grating coupler of this comparative example does not satisfy the requirement that |κ2|/|κ1| is 3 or more, and conversely, |κ1|/|κ2| is 3 or more (|κ2|/|κ1| is less than 3).

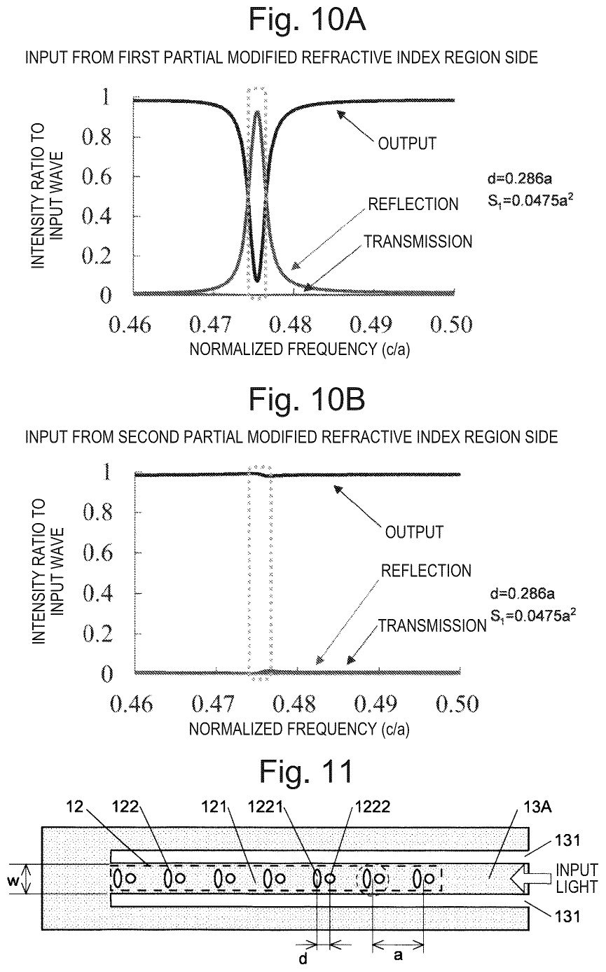

For the waveguide grating coupler of this comparative example, the intensity of the output light, the reflected light, and the transmitted light in a case (FIG. 10A) where light is incident from the input port 13 side (the first partial modified refractive index region 1221 side of the modified refractive index region 122) and a case (FIG. 10B) where light is incident from the opposite side of the input port 13 (the second partial modified refractive index region 1222 side) were obtained by calculation. As a result, as illustrated in FIG. 10A, it can be seen that when input light having a normalized frequency of around 0.475 is input from the input port 13 side, the intensity of the reflected light increases, and characteristics required as a waveguide grating coupler cannot be obtained. Since |κ1|/|κ2| is 3 or more, switching between the first direction and the second direction satisfies the requirement that the ratio of the coupling coefficients is 3 or more. Therefore, when input light is input from the opposite side of the input port 13, such reflection hardly occurs.

Therefore, as illustrated in FIG. 11, in the configuration in which the waveguide end portion on the side opposite to the input port 13 in the example of FIG. 8 is a new input port 13A and the input port 13 side in the example of FIG. 8 is a waveguide end portion on the side opposite to the input port 13A, a waveguide grating coupler of a second example in which the grating 12 has the same configuration as that of the waveguide grating coupler 12 of the comparative example is introduced. In this example, it can be seen that when light is incident from the input port 13A side (the second partial modified refractive index region 1222 side), the light is output with almost no reflection or transmission, and functions as a grating coupler (FIG. 10B).

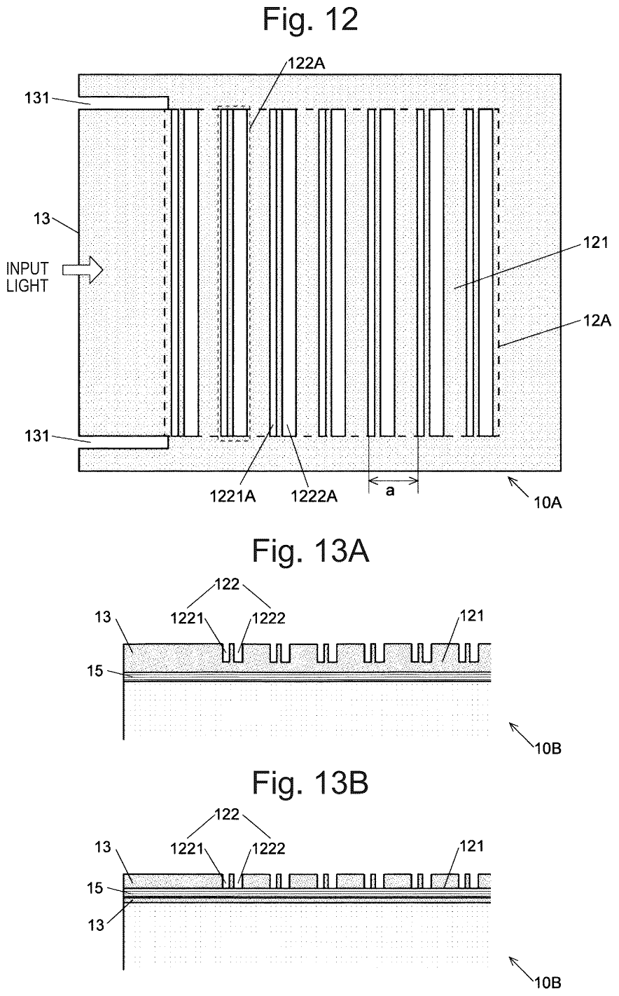

Although the example using the point-like modified refractive index regions 122 has been described so far, a linear modified refractive index regions may be used. A grating coupler 10A illustrated in FIG. 12 includes a grating 12A in which a large number of linear modified refractive index regions 122A each including a first partial modified refractive index region 1221A and a second partial modified refractive index region 1222A formed by grooves having mutually-different widths are disposed one-dimensionally with a period length a in the width direction of the grooves. By adjusting the widths of the first partial modified refractive index region 1221A and the second partial modified refractive index region 1222A, it is possible to set |κ2|/|κ1| to 3 or more. The number of grooves (partial modified refractive index regions) may be three or more.

As a modification of the grating coupler of the first embodiment, as illustrated in FIGS. 13A and 13B, a light amplification layer (active layer) 15 may be provided on the surface (FIG. 13A) or the inside (FIG. 13B) of the base member 121 of the grating 12. As the light amplification layer 15, a normal active layer used in a laser element or the like, which amplifies light whose wavelength in the grating 12 is an integral multiple or an integral fraction of the period length al of the modified refractive index regions with respect to the first direction, is used. A grating coupler 10B including such light amplification layer 15 functions as an optical amplifier that amplifies input light by the light amplification layer and then outputs the amplified input light with high efficiency.

In each of the examples described above, the two grooves 131 are formed in the base member 11, and the region between the grooves is the input port 13, but the grooves 131 may be omitted.

### (2) Second Embodiment

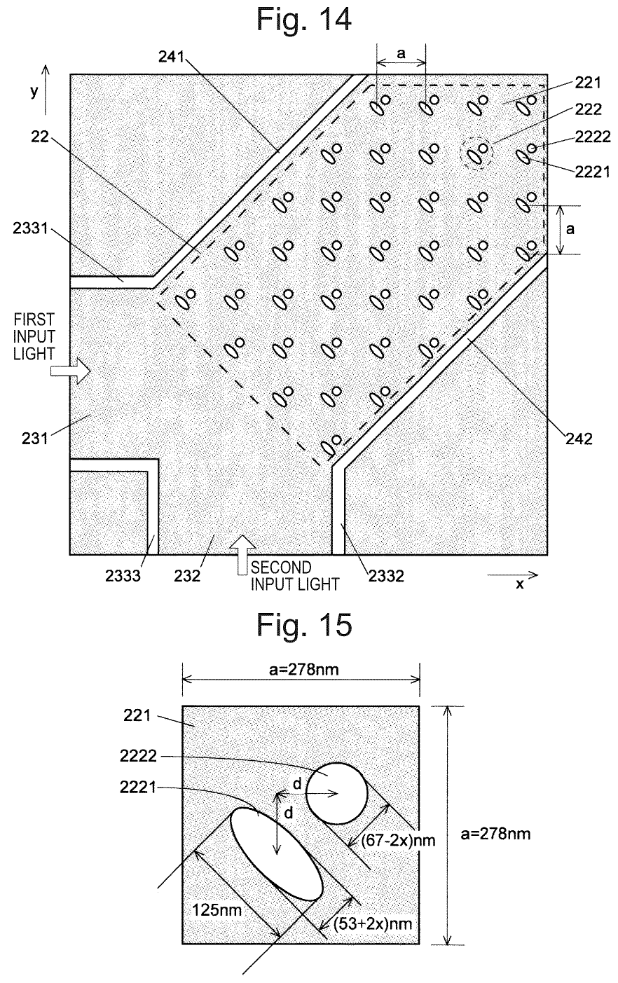

FIG. 14 illustrates a top view of a grating coupler 20 of a second embodiment. The grating coupler 20 includes a plate-shaped base member 221 made of Si provided on a pedestal made of SiO₂ (which is not illustrated and the same as the pedestal 11 in the first embodiment), and a grating 22 including modified refractive index regions 222 disposed in a square lattice shape with a period length a in the base member 221. One of the directions of the two basic translation vectors in the square lattice is an x direction, and the other is a y direction. The modified refractive index region 222 includes a pair of a first partial modified refractive index region 2221 having an elliptical planar shape and a second partial modified refractive index region 2222 having a circular planar shape. The minor axis of the ellipse of the first partial modified refractive index region 2221 faces a direction inclined by +45° (direction in which y also increases as x increases) with respect to the x direction, and the centroid of the first partial modified refractive index region 2221 and the centroid of the second partial modified refractive index region 2222 are separated from each other in the direction of the minor axis.

The shape of the modified refractive index region 222 is set such that, when a +x direction (a direction from the left to the right in FIG. 14) is a first direction, a −x direction (a direction from the right to the left in FIG. 14) is a second direction, a +y direction (a direction from the bottom to the top in FIG. 14) is a third direction, and a −y direction (a direction from the top to the bottom in FIG. 14) is a fourth direction, the ratio |κ2|/|κ1| of a second coupling coefficient κ2 to a first coupling coefficient κ1 is set to be 3 or more, the first coupling coefficient k1 being an index indicating the intensity of light reflected at the same phase and the same amplitude in the second direction and the fourth direction among light traveling so as to have the same phase and the same amplitude in the first direction and the third direction, the second coupling coefficient k2 being an index indicating the intensity of light reflected at the same phase and the same amplitude in the first direction and the third direction among light traveling so as to have the same phase and the same amplitude in the second direction and the fourth direction.

A detailed design of the shape of the modified refractive index region 222 will be described later.

In the base member 221, two grooves (a first outer edge groove 241 and a second outer edge groove 242) inclined at +45° with respect to the x direction and parallel to each other are formed, and the modified refractive index regions 222 are provided between the first outer edge groove 241 and the second outer edge groove 242. In addition, the base member 221 is provided with a first input port groove 2331 extending in the −x direction from one end of the first outer edge groove 241 on the negative side in the x direction and a second input port groove 2332 extending in the −y direction from one end of the second outer edge groove 242 on the negative side in the x direction. Furthermore, the base member 221 is provided with a third input port groove 2333 formed by connecting a groove parallel to the first input port groove 2331 and disposed to be separated in the −y direction and a groove parallel to the second input port groove 2332 and disposed to be separated in the −x direction. A region between the first input port groove 2331 and the third input port groove 2333 functions as the first input port 231, and a region between the second input port groove 2332 and the third input port groove 2333 functions as the second input port 232.

A first input-side optical element is disposed at an end portion of the base member 221 in the first input port 231, and a second input-side optical element is disposed at an end portion of the base member 221 in the second input port 232. In addition, an output-side optical element is disposed on the upper surface of the grating 22 (both are not illustrated). Each of these optical elements inputs/outputs light having a wavelength a in the grating 22.

The operation of the grating coupler 20 of the second embodiment will be described. First input light traveling in the +x direction is input from the first input-side optical element to the first input port 231. In addition, second input light traveling in the +y direction is input from the second input-side optical element to the second input port 232. Both the first input light and the second input light are introduced into the grating 22, diffracted by the grating 22 in a direction perpendicular to the base member 221, and extracted from the surface of the grating 22 as output light. The output light thus extracted is introduced into the output-side optical element.

There is a possibility that light incident from the vicinity of the end portion on the negative side of y among incident light 1 from the first input port 231 and light incident from the vicinity of the end portion on the negative side of x among incident light 2 from the second input port 232 partially passes through the grating 22 because a sufficient number of modified refractive index regions 222 do not exist on a path of traveling in the grating 22. In order to prevent light from passing through the grating 22 by reflecting such light, the first outer edge groove 241 and the second outer edge groove 242 are provided.

Hereinafter, an example in which the shape and size of the modified refractive index region 222 are designed so that |κ2|/|κ1| is 3 or more will be described in detail.

Parameters for defining κ1 and κ2 used in this design example will be described with reference to FIG. 15. The refractive index of the base member 121 (Si) was set to 3.4, and the refractive index of the modified refractive index region 222 (air) was set to 1. The lattice constant is a=278 nm. The centroid of the first partial modified refractive index region 2221 and the centroid of the second partial modified refractive index region 2222 are separated by a distance d in the x direction and the y direction, respectively. As this distance d, four examples of 0.266a, 0.272a, 0.278a, and 0.284a were prepared. The length of the major axis of the ellipse of the first partial modified refractive index region 2221 was fixed to 125 nm, the length of the minor axis was set to (53+2x) nm, the diameter of the circle of the second partial modified refractive index region 2222 was set to (67−2x) mm, and four examples of 2x=1.5 nm, 3.0 nm, 4.5 nm, and 6.0 nm were prepared.

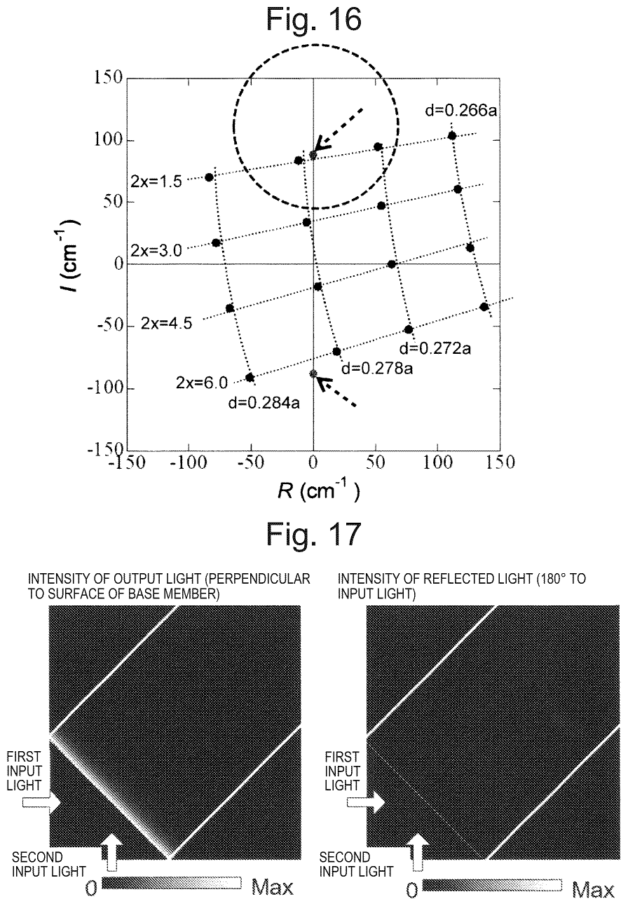

For 16 examples obtained by combining the examples of the four distances d and the examples of four 2x described above, a Hermitian coupling coefficient R±iI and a non-Hermitian coupling coefficient iμ for obtaining the first coupling coefficient κ1 and the second coupling coefficient κ2 were obtained using the method described in Non Patent Literature 2. FIG. 16 illustrates the calculation results. The calculation results of the value μ representing the imaginary part (the real part is 0) of the non-Hermitian coupling coefficient hardly depend on the intercentroid distance d and 2x that is a value defining the minor axis of the ellipse of the first partial modified refractive index region 2221 and the diameter of the second partial modified refractive index region 2222, and were almost the same value (about 87 cm⁻¹). Among the 18 data points illustrated in FIG. 16, 16 data points excluding 2 points indicated by dashed arrows indicate calculation results of the 16 examples described above. The two data points indicated by the dashed arrows are points at which R=0, I=+μ, and R=0, I=−μ, respectively. The former indicates R and I when the intensity of the reflected light becomes 0, and the latter indicates R and I when the intensity of the reflected light becomes 1. At data points (d=0.272a, 2x=1.5 nm and d=0.278a, 2x=1.5 nm) in a circle indicated by a thick dashed line in FIG. 16, |κ2|/|κ1| is 3 or more.

FIG. 17 illustrates results obtained by calculating intensity distributions of output light output in a direction perpendicular to the base member 221 and reflected light reflected in the grating 22 and having a traveling direction changed by 180° in a case of d=0.278a and 2x=1.5 nm. It can be seen that, when the first input light is input from the first input port 231 and the second input light is input from the second input port 232, the output light is output from the grating 22 in a direction perpendicular to the base member 221 (the left diagram of FIG. 17), whereas the reflected light is hardly generated (the right diagram). From this result, it can be seen that the grating coupler 20 of the second embodiment can efficiently output the light input from the first input port 231 and the second input port 232 in the direction perpendicular to the base member 221 in the case of d=0.278a and 2x=1.5 nm.

Also in the second embodiment, similarly to the first embodiment, by providing a light amplification layer (active layer) on the surface or inside of the grating 22, it can be used as an optical amplifier.

While the two embodiments of the grating coupler according to the present invention and their modifications have been described above, the present invention is not limited to these examples, and various modifications can be made within the scope of the gist of the present invention.

### Modes

A person skilled in the art can understand that the previously described illustrative embodiment is a specific example of the following modes of the present invention.

(Clause 1) A grating coupler according to Clause 1 includes
a grating including a plate-shaped base member and modified refractive index regions having a refractive index different from that of the base member, the modified refractive index regions either being point-like and periodically disposed two-dimensionally or one-dimensionally in the base member, or being linear and periodically disposed one-dimensionally in the base member,
in which the modified refractive index regions each have a planar shape in which a ratio |κ2|/|κ1| of an absolute value |κ2| of a second coupling coefficient to an absolute value |κ1| of a first coupling coefficient is 3 or more, the first coupling coefficient being an index indicating intensity at which light traveling in a first direction parallel to the base member is reflected in a second direction different by 180° from the first direction, the second coefficient being an index indicating intensity at which light traveling in the second direction is reflected in the first direction.

(Clause 2) A grating coupler according to Clause 2 is the grating coupler according to Clause 1 in which each of the modified refractive index regions includes a pair of a first partial modified refractive index region and a second partial modified refractive index region, the second partial modified refractive index region being different from the first partial modified refractive index region in either shape or area, or in both shape and area.

(Clause 3) A grating coupler according to Clause 3 is the grating coupler according to Clause 1 or 2 further including, at an end portion of the base member on a starting point side in the first direction, a light input portion from which input light is input.

(Clause 4) A grating coupler according to Clause 4 is the grating coupler according to any one of Clause 1 to Clause 3 further including a light amplification layer configured to amplify light having a predetermined wavelength in the base member in the grating or on a surface of the base member.

### REFERENCE SIGNS LIST

10, 10A, 10B, 20 . . . Grating Coupler
11 . . . Pedestal
12, 12A, 22 . . . Grating
121, 221 . . . Base Member
122, 122A, 222 . . . Modified Refractive Index Region
1221, 1221A, 2221 . . . First Partial Modified Refractive Index Region
1222, 1222A, 2222 . . . Second Partial Modified Refractive Index Region
13 . . . Input Port
131 . . . Input Port Groove
15 . . . Active Layer (Light Amplification Layer)
231 . . . First Input Port
232 . . . Second Input Port
2331 . . . First Input Port Groove
2332 . . . Second Input Port Groove
2333 . . . Third Input Port Groove
241 . . . First Outer Edge Groove
242 . . . Second Outer Edge Groove
91 . . . Input-side Optical Element
92 . . . Output-side Optical Element

1. A grating coupler comprising
a grating including a plate-shaped base member and modified refractive index regions having a refractive index different from that of the base member, the modified refractive index regions either being point-like and periodically disposed two-dimensionally or one-dimensionally in the base member, or being linear and periodically disposed one-dimensionally in the base member, wherein
the modified refractive index regions each have a planar shape in which a ratio |κ2|/|κ1| of an absolute value |κ2| of a second coupling coefficient to an absolute value |κ1| of a first coupling coefficient is 3 or more, the first coupling coefficient being an index indicating intensity at which light traveling in a first direction parallel to the base member is reflected in a second direction different by 180° from the first direction, the second coefficient being an index indicating intensity at which light traveling in the second direction is reflected in the first direction.

2. The grating coupler according to claim 1, wherein each of the modified refractive index regions includes a pair of a first partial modified refractive index region and a second partial modified refractive index region, the second partial modified refractive index region being different from the first partial modified refractive index region in either shape or area, or in both shape and area.

3. The grating coupler according to claim 1, further comprising, at an end portion of the base member on a starting point side in the first direction, a light input portion from which input light is input.

4. The grating coupler according to claim 1, further comprising a light amplification layer configured to amplify light having a predetermined wavelength in the base member in the grating or on a surface of the base member.
